(19) United States
(12) Patent Application Publication
(10) Pub. No.: US 2025/0329644 A1
(43) Pub. Date: Oct. 23, 2025

(54) CONTACT STRUCTURES IN THREE-DIMENSIONAL SEMICONDUCTIVE DEVICES

(71) Applicant: Yangtze Memory Technologies Co., Ltd., Wuhan (CN)

(72) Inventors: Yang CHEN, Wuhan (CN); Zhong ZHANG, Wuhan (CN); Kun ZHANG, Wuhan (CN); Di WANG, Wuhan (CN); Wenxi ZHOU, Wuhan (CN)

(21) Appl. No.: 18/789,635

(22) Filed: Jul. 30, 2024

Related U.S. Application Data
(63) Continuation of application No. PCT/CN2024/088512, filed on Apr. 18, 2024.

(51) Int. Cl. H01L 23/528; G11C 16/04; H01L 23/532; H10B 41/10; H10B 41/27; H10B 41/35; H10B 43/10; H10B 43/27; H10B 43/35

(52) U.S. Cl. CPC H01L 23/5283; G11C 16/0483; H01L 23/528; H01L 23/53295; H10B 41/10; H10B 41/27; H10B 41/35; H10B 43/10; H10B 43/27; H10B 43/35

(57) ABSTRACT

Devices and systems including contact structures, and methods for forming the contact structures in three-dimensional semiconductive devices are provided. In one aspect, a semiconductor device includes contact structures, where the contact structures are positioned along a first direction in a block of the semiconductor device. The contact structures are grouped into contact structure groups based on depths of the contact structures along a second direction perpendicular to the first direction, each contact structure group including one or more respective contact structures. Between two adjacent contact structures of a first contact structure group along the first direction, a contact structure of a second contact structure group different from the first contact structure group is positioned.

### CROSS-REFERENCE TO RELATED APPLICATIONS

This application is a continuation of International Application No. PCT/CN2024/088512, filed on Apr. 18, 2024, the disclosure of which is hereby incorporated by reference in its entirety.

### TECHNICAL FIELD

The present disclosure relates to semiconductor devices and fabrication processes for semiconductor devices.

### BACKGROUND

Semiconductor devices, e.g., memory devices, can have various structures to increase a density of memory cells and lines on a chip. For example, three-dimensional (3D) memory devices are attractive due to their capability to increase an array density by stacking more layers within a similar footprint. A 3D memory device normally includes a memory array of memory cells and peripheral circuits for facilitating operations of the memory array. The memory cells can include vertical structures.

### SUMMARY

The present disclosure describes methods, devices, systems and techniques for managing vertical structures in three-dimensional (3D) semiconductor devices.

One aspect of the present disclosure features semiconductor device including contact structures, where the contact structures are positioned along a first direction in a block of the semiconductor device, the contact structures are grouped into contact structure groups based on depths of the contact structures along a second direction perpendicular to the first direction, each contact structure group including one or more respective contact structures, and between two adjacent contact structures of a first contact structure group along the first direction, a contact structure of a second contact structure group different from the first contact structure group is positioned.

In some implementations, the semiconductor device includes a stack of conductive layers and isolating layers alternating with each other along the second direction, where each contact structure extends through at least a part of the stack of conductive layers and isolating layers, each contact structure is coupled to a respective conductive layer, and a depth of a contact structure along the second direction is determined by a depth, along the second direction, of a conductive layer coupled to the contact structure.

In some implementations, all contact structures of the first contact structure group are coupled to first conductive layers, all contact structures of the second contact structure group are coupled to second conductive layers, and the first conductive layers are on a first side of the second conductive layers along the second direction.

In some implementations, the contact structure groups include a third contact structure group, all contact structures of the third contact structure group are coupled to third conductive layers, the third conductive layers are on a second side of the second conductive layers along the second direction, the second side is opposite to the first side, and a contact structure of the third contact structure group is positioned between a contact structure of the first contact structure group and a contact structure of the second contact structure group.

In some implementations, the block includes one finger.

In some implementations, the first direction and a third direction perpendicular to the first direction form a first plane, the second direction is perpendicular to the first plane, a projection of each of the contact structures on the first plane includes a respective center point, each center point has a respective height along the third direction, and the contact structures are positioned along the first direction in a pattern where heights of center points of the contact structures alternate.

In some implementations, two rows of contact structures of the first contact structure group are positioned parallelly along the first direction, one row of contact structures of the second contact structure group are positioned along the first direction, and a depth associated with the first contact structure group is smaller than a depth associated with the second contact structure group.

In some implementations, the first direction and a third direction perpendicular to the first direction form a first plane, the second direction is perpendicular to the first plane, a projection of a contact structure of the first contact structure group on the first plane has a length along the third direction, and the length is smaller than one half of a height of the block along the third direction.

In some implementations, the block includes two word lines, each word line is positioned on a side of the block, and a contact structure of the contact structures is coupled to at least one of the two word lines.

In some implementations, a first contact structure and a second contact structure of the first contact structure group are adjacent to each other along a third direction perpendicular to the first direction, the first contact structure is coupled to a first side of the block via a first interconnect line, the second contact structure is coupled to a second side of the block via a second interconnect line, and at least a part of the first interconnect line and at least a part of the second interconnect line overlap on the third direction.

Another aspect of the present disclosure features a method including grouping contact structures to be formed in a semiconductor device into contact structure groups based on depths of the contact structures along a second direction, each contact structure group including one or more respective contact structures, and forming the contact structures along a first direction perpendicular to the second direction in a block of the semiconductor device, where forming the contact structures includes forming a contact structure of a second contact structure group different from a first contact structure group between two adjacent contact structures of the first contact structure group along the first direction.

In some implementations, the method includes forming a stack of conductive layers and isolating layers alternating with each other along the second direction, where each contact structure extends through at least a part of the stack of conductive layers and isolating layers, each contact structure is coupled to a respective conductive layer, and a depth of a contact structure along the second direction is determined by a depth, along the second direction, of a conductive layer coupled to the contact structure.

In some implementations, forming the contact structures includes coupling all contact structures of the first contact structure group to first conductive layers, and coupling all contact structures of the second contact structure group to second conductive layers, where the first conductive layers are on a first side of the second conductive layers along the second direction.

In some implementations, the contact structure groups include a third contact structure group, and where forming the contact structures includes forming a contact structure of the third contact structure group between a contact structure of the first contact structure group and a contact structure of the second contact structure group, and coupling all contact structures of the third contact structure group to third conductive layers, where the third conductive layers are on a second side of the second conductive layers along the second direction, and the second side is opposite to the first side.

In some implementations, the block includes one finger.

In some implementations, the first direction and a third direction perpendicular to the first direction form a first plane, the second direction is perpendicular to the first plane, a projection of each of the contact structures on the first plane includes a respective center point, each center point has a respective height along the third direction, and forming the contact structures includes forming the contact structures along the first direction in a pattern where heights of center points of the contact structures alternate.

In some implementations, forming the contact structures includes forming two rows of contact structures of the first contact structure group parallelly along the first direction, and forming one row of contact structures of the second contact structure group along the first direction, where a depth associated with the first contact structure group is smaller than a depth associated with the second contact structure group.

In some implementations, the first direction and a third direction perpendicular to the first direction form a first plane, the second direction is perpendicular to the first plane, a projection of a contact structure of the first contact structure group on the first plane has a length along the third direction, and the length is smaller than one half of a height of the block along the third direction.

In some implementations, the method includes forming two word lines in the block, where each word line is formed on a side of the block; and coupling a contact structure of the contact structures to at least one of the two word lines.

A further aspect of the present disclosure features a system, including a semiconductor device including contact structures, where the contact structures are positioned along a first direction in a block of the semiconductor device, the contact structures are grouped into contact structure groups based on depths of the contact structures along a second direction perpendicular to the first direction, each contact structure group including one or more respective contact structures, and between two adjacent contact structures of a first contact structure group along the first direction, a contact structure of a second contact structure group different from the first contact structure group is positioned. The system includes a memory controller electrically connected to the semiconductor device, where the memory controller is configured to control the semiconductor device.

Implementations of the present disclosure can provide one or more of the following technical advantages and/or benefits. For example, in some cases, the contact structures are grouped into contact structure groups based on depths of the contact structures along the z-direction. In some examples, the contact structures can be positioned along the x-direction in a pattern where depths of the contact structures alternate. For example, two deeper contact structures can be separated by positioning a shallower contact structure in between. Therefore, the distance between the two deeper contact structures is increased. This can improve the process window of the deeper contact structures, and reduce the difficulty of the fabrication process of the deeper contact structures. Moreover, because the two adjacent contact structures are in different contact structure groups having different depths, the two conductive layers coupled to by the two adjacent contact structures can have a large distance along the z-direction. This can enhance the structural stability of the 3D memory device.

In some cases, the contact structures are divided into even-depth contact structures and odd-depth contact structures. Contact structures of a contact structure group can be positioned in a pattern that the contact structures having odd depths (e.g., 1, 3, 5, and so on) are positioned on one half of a block along the x-direction, whereas the contact structures having even depths (e.g., 2, 4, 6, and so on) are positioned on the other half of the block along the x-direction. The grouping of even-depth contact structures on one side and the grouping of odd-depth contact structures on the other side can more efficiently and effectively detect Bright Voltage Contrast (BVC) leakages.

In some cases, contact structures of a contact structure group are positioned in a pattern that the deep contact structures are positioned on two sides of the block along the x-direction, whereas the shallow contact structures are positioned at the center of the block along the x-direction. By positioning the deep contact structures on two sides of the block and placing the shallow contact structures at the center of the block, a process window of the contact structures can be increased.

In some cases, contact structures corresponding to the bottom select gates (BSGs) are positioned at the center of a contact region. Positioning the contact structures corresponding to the BSGs at the center of the contact region can enhance the BSG word line driver control.

In some cases, the contact structures are positioned along the x-direction in a wave-like pattern where heights of center points of the contact structures alternate. By positioning the contact structures in this wave-like pattern, the contact structures can be closely positioned by reducing the distances between adjacent contact structures. This can reduce the overall length of the contact region along the x-direction and thus increase the space for the core array regions. The increased space for the core array regions can in turn increase the space for channel structures, and thus increase the memory density.

In some cases, two rows of contact structures of a contact structure group are positioned parallelly along the x-direction. By positioning the contact structures in two rows, the density of the contact structures in the contact region can be increased. This can reduce the overall length of the contact region along the x-direction and thus increase the space for the core array regions. The increased space for the core array regions can in turn increase the space for channel structures, and thus increase the memory density.

The techniques can be applied to various types of semiconductor devices, volatile memory devices, such as DRAM memory devices, or non-volatile memory (NVM) devices, such as NAND flash memory, NOR flash memory, resistive random-access memory (RRAM), phase-change memory (PCM) such as phase-change random-access memory (PCRAM), spin-transfer torque (STT)-Magnetoresistive random-access memory (MRAM), among others. The techniques can also be applied to charge-trapping based memory devices, e.g., silicon-oxide-nitride-oxide-silicon (SONOS) memory devices, and floating-gate based memory devices. The techniques can be applied to three-dimensional (3D) memory devices. The techniques can be applied to various memory types, such as SLC (single-level cell) devices, MLC (multi-level cell) devices like 2-level cell devices, TLC (triple-level cell) devices, QLC (quad-level cell) devices, or PLC (penta-level cell) devices. Additionally or alternatively, the techniques can be applied to various types of devices and systems, such as secure digital (SD) cards, embedded multimedia cards (eMMC), or solid-state drives (SSDs), embedded systems, among others.

The details of one or more implementations of the subject matter of this present disclosure are set forth in the accompanying drawings and the description below. Other features, aspects, and advantages of the subject matter will become apparent from the description, the drawings, and the claims.

### BRIEF DESCRIPTION OF THE DRAWINGS

The accompanying drawings, which are incorporated herein and form a part of the present disclosure, illustrate aspects of the present disclosure and, together with the description, further serve to explain the principles of the present disclosure and to enable a person of ordinary skill in the pertinent art to make and use the present disclosure.

FIG. 1 illustrates a plan view of a 3D memory device having contact structures, according to some aspects of the present disclosure.

FIG. 2 illustrates a top perspective view of 3D memory device having contact structures, according to some aspects of the present disclosure.

FIG. 3 illustrates an enlarged top perspective view of 3D memory device having contact structures, according to some aspects of the present disclosure.

FIG. 4 illustrates a plain view of an example contact region in an example block of an example 3D memory device, according to some aspects of the present disclosure.

FIG. 5 depicts a cross-sectional view of the block along cut line AA′ shown in FIG. 4, according to some aspects of the present disclosure.

FIG. 6 depicts an example cross-sectional view of the block along cut line BB′ shown in FIG. 4, according to some aspects of the present disclosure.

FIG. 7 depicts another example cross-sectional view of the block along cut line BB′ shown in FIG. 4, according to some aspects of the present disclosure.

FIG. 8 depicts yet another example cross-sectional view of the block along cut line BB′ shown in FIG. 4, according to some aspects of the present disclosure.

FIG. 9 illustrates a plain view of an example contact region in an example block of an example 3D memory device, according to some aspects of the present disclosure.

FIG. 10 depicts a cross-sectional view of the block along cut line AA′ shown in FIG. 9, according to some aspects of the present disclosure.

FIG. 11 illustrates a plain view of an example contact region in an example block of an example 3D memory device, according to some aspects of the present disclosure.

FIG. 12 depicts a cross-sectional view of the block along cut line AA′ shown in FIG. 11, according to some aspects of the present disclosure.

FIG. 13 depicts an example of a block that employs two different types of contact structure positionings in different regions of the block, according to some aspects of the present disclosure.

FIG. 14 is a flow chart of an example process of forming contact structures in a semiconductor device, according to some aspects of the present disclosure.

FIG. 15 illustrates a block diagram of a system having one or more semiconductor devices (e.g., memory devices), according to some aspects of the present disclosure.

Like reference numbers and designations in the various drawings indicate like elements. It is also to be understood that the various exemplary implementations shown in the figures are merely illustrative representations and are not necessarily drawn to scale.

### DETAILED DESCRIPTION

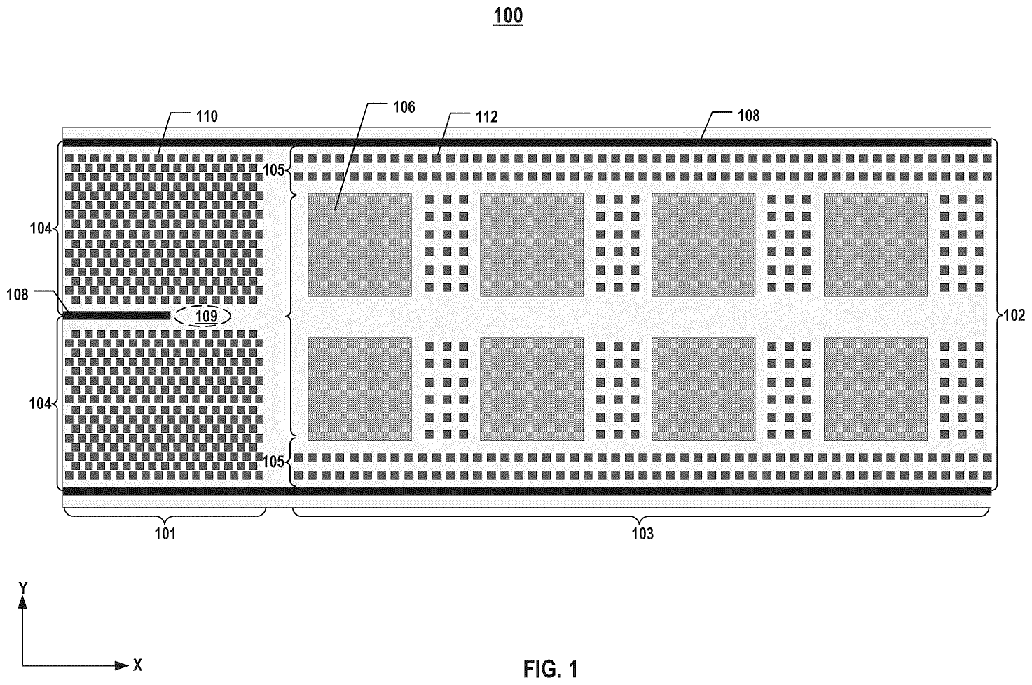

FIG. 1 illustrates a plan view of a 3D memory device 100 having contact structures 106, according to some aspects of the present disclosure. In some implementations, 3D memory device 100 is a NAND Flash memory device in which memory cells are provided in the form of an array of NAND memory strings. It is noted that x and y axes are included in FIG. 1 to illustrate two orthogonal (perpendicular) directions in the wafer plane. The x-direction (also referred to herein as the first direction) is the word line direction of 3D memory device 100, and the y-direction (also referred to herein as the third direction) is the bit line direction of 3D memory device 100.

As shown in FIG. 1, 3D memory device 100 can include one or more blocks 102 arranged in the y-direction (the bit line direction) separated by parallel slit structures 108, such as gate line slits (GLSs). In some implementations in which 3D memory device 100 is a NAND Flash memory device, each block 102 is the smallest erasable unit of the NAND Flash memory device. Each block 102 can further include multiple fingers 104 in the y-direction separated by some of slit structures 108 with “H” cuts 109.

As shown in FIG. 1, 3D memory device 100 can be divided into at least a core array region 101 in which an array of channel structures 110 are formed, as well as a contact region 103 in which contact structures 106 are formed. Core array region 101 and contact region 103 are arranged in the x-direction (the word line direction), according to some implementations. It is understood that although one core array region 101 and one contact region 103 are illustrated in FIG. 1, multiple core array regions 101 and/or multiple contact regions 103 can be included in 3D memory device 100. For example, one contact region 103 between two core array regions 101 can be included in the x-direction of the 3D memory device 100. It is also understood that FIG. 1 only illustrates portions of core array region 101 that are adjacent to contact region 103.

Contact region 103 can include conductive portions 105 and dielectric portions 107 arranged in the y-direction. As shown in FIG. 1, contact structures 106 are disposed in dielectric portion 107, while dummy channel structures 112 are disposed in conductive portion 105 of contact region 103 to provide mechanical support and/or load balancing, according to some implementations. In some implementations (e.g., as shown in FIG. 1), dummy channel structures 112 are disposed in dielectric portion 107 of contact region 103 as well, for example, between contact structures 106 in the x-direction. In some implementations, dummy channel structures 112 are not disposed in dielectric portion 107 of contact region 103. That is, the dummy channel structures 112 are only disposed in conductive portion 105 of contact region 103. As shown in FIG. 1, each finger 104 of 3D memory device 100 can include one row of contact structures 106 disposed in dielectric portion 107 of contact region 103. It is understood that the layout and arrangement of contact structures 106, as well as the shape of each contact structure 106, may vary in different examples, as described in more details below.

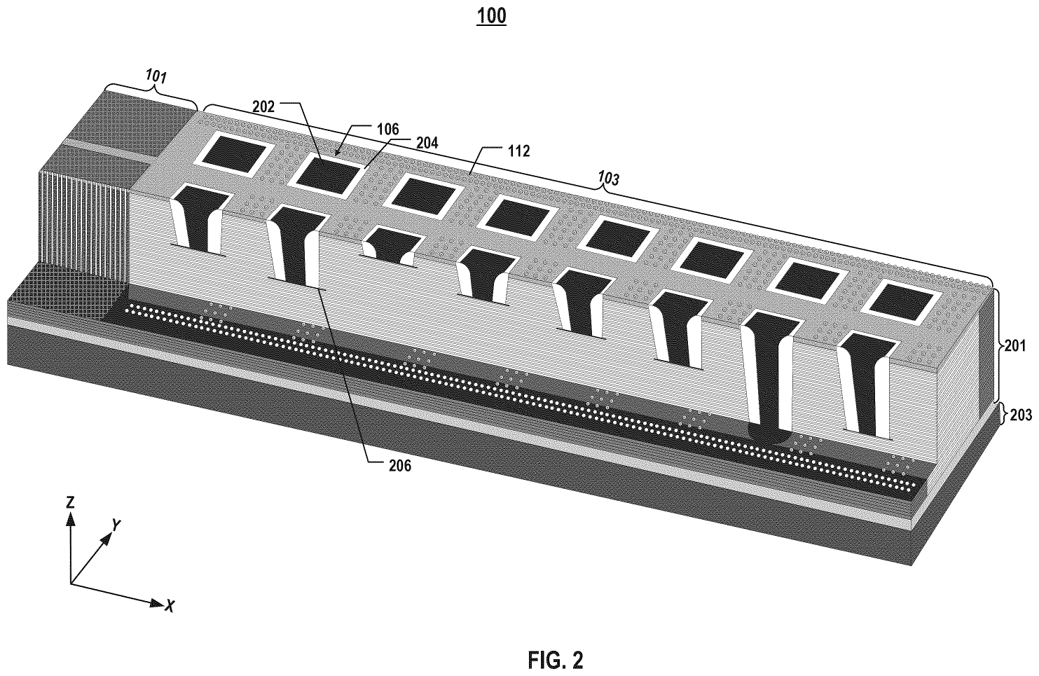

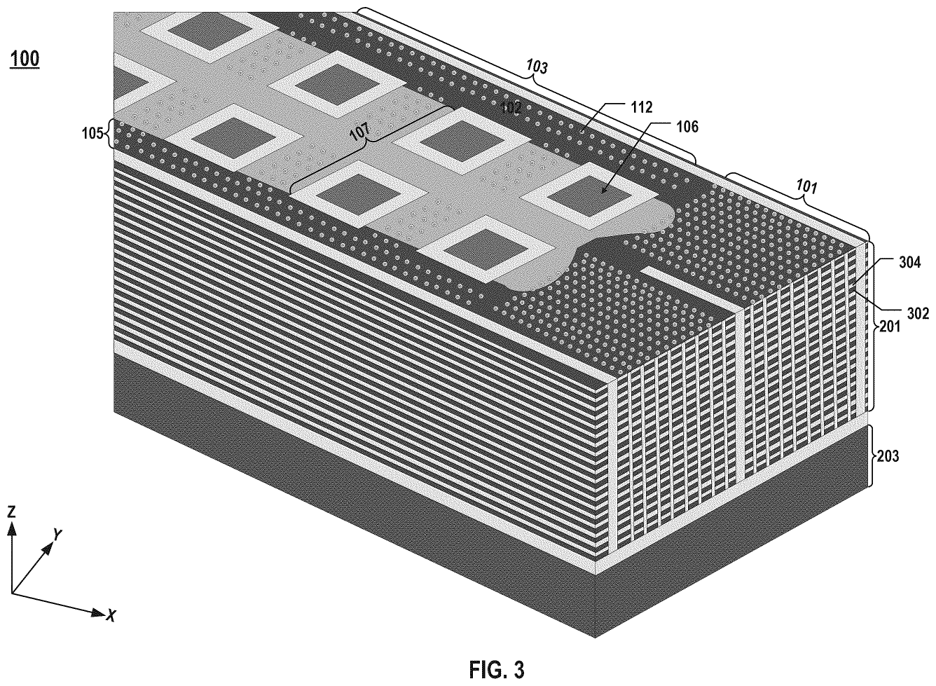

FIG. 2 illustrates a top perspective view of 3D memory device 100 having contact structures 106, according to some aspects of the present disclosure. FIG. 3 illustrates an enlarged top perspective view of 3D memory device 100 having contact structures 106, according to some aspects of the present disclosure. As shown in FIGS. 2 and 3, a stack structure 201 can be formed on a substrate 203, which can include silicon (e.g., single crystalline silicon), silicon germanium (SiGe), gallium arsenide (GaAs), germanium (Ge), silicon on insulator (SOI), or any other suitable materials. In some implementations, substrate 203 includes single crystalline silicon, which is part of the wafer on which 3D memory device 100 is fabricated, either in its native thickness or being thinned. In some implementations, substrate 203 includes, for example, polysilicon, which is a semiconductor layer replacing the part of wafer on which 3D memory device 100 is fabricated. It is noted that x, y, and z axes are included in FIGS. 2 and 3 to further illustrate the spatial relationship of the components in 3D memory device 100. Substrate 203 of 3D memory device 100 includes two lateral surfaces extending laterally in the x-y plane: a top surface on the front side of the wafer on which stack structure 201 can be formed, and a bottom surface on the backside opposite to the front side of the wafer. The z-axis is perpendicular to both the x and y axes. As used herein, whether one component (e.g., a layer or a device) is “on,” “above,” or “below” another component (e.g., a layer or a device) of 3D memory device 100 is determined relative to substrate 203 of 3D memory device 100 in the z-direction (the vertical direction perpendicular to the x-y plane, also referred to herein as the second direction) when substrate 203 is positioned in the lowest plane of 3D memory device 100 in the z-direction. The same notion for describing the spatial relationship is applied throughout the present disclosure.

As shown in FIG. 3, stack structure 201 can include vertically interleaved first material layers 302 and second material layers 304 that are different from first material layers 302. First material layers 302 and second material layers 304 can alternate in the vertical direction (i.e., the z-direction). In some implementations, stack structure 201 can include a plurality of material layer pairs stacked vertically in the z-direction, each of which includes first material layer 302 and second material layer 304. The number of the material layer pairs in stack structure 201 can determine the number of memory cells in 3D memory device 100.

In some implementations, 3D memory device 100 is a NAND Flash memory device, and stack structure 201 is a stacked storage structure through which NAND memory strings are formed. As shown in FIG. 3, first material layers 302 can have different materials in different regions/portions of 3D memory device 100. Thus, stack structure 201 can be viewed as having a number of stack structures with different materials of first material layers 302 for case of description in the present disclosure. In some implementations, core array region 101 and conductive portion 105 of contact region 103 include a conductive stack structure having interleaved conductive layers and first dielectric layers. That is, first material layers 302 of stack structure 201 can be conductive layers in core array region 101 and conductive portion 105 of contact region 103. In some implementations, dielectric portion 107 of contact region 103 includes a dielectric stack structure having interleaved second dielectric layers and the first dielectric layers. That is, first material layers 302 of stack structure 201 can be the second dielectric layers in dielectric portion 107 of contact region 103.

Second material layers 304 of stack structure can be the same in the conductive stack structure and the dielectric stack structure across core array region 101 and contact region 103. For example, the second material layers 304 can be the first dielectric layers in the conductive stack structure and the dielectric stack structure across core array region 101 and contact region 103.

In some cases, the formation of stack structure 201 with different materials of first material layers 302 in different regions/portions can be achieved by controlling the different degrees and scopes of the gate replacement process in different regions/portions. For example, stack structure 201 can undergo a complete gate replacement process in core array region 101 to replace all the second dielectric layers with the conductive layers. Also, the stack structure 201 can undergo a partial gate replacement process in contact region 103 to replace some of the second dielectric layers with the conductive layers in conductive portion 105, leaving the remainders of the second dielectric layers in dielectric portion 107.

In some implementations, each conductive layer in the conductive stack structure in core array region 101 and conductive portion 105 of contact region 103 functions as a gate line of the NAND memory strings (e.g., in the forms of channel structures 110) in core array region 101, as well as a word line extending laterally from the gate line and ending in conductive portion 105 of contact region 103 for contact/fan-out through contact structures 106. The word lines (i.e., the conductive layers) at different depths/levels of the conductive stack structure each extends laterally in core array region 101 and conductive portion 105 of contact region 103, but are discontinuous (e.g., being replaced by the second dielectric layers) in dielectric portion 107 of contact region 103, according to some implementations.

The conductive layers can include conductive materials including, but not limited to, tungsten (W), cobalt (Co), copper (Cu), aluminum (Al), titanium nitride (TiN), polycrystalline silicon (polysilicon), doped silicon, silicides, or any combination thereof. The dielectric layers can include dielectric materials including, but not limited to, silicon oxide, silicon nitride, silicon oxynitride, or any combination thereof. The first dielectric layers and the second dielectric layers can have different dielectric materials, such as silicon oxide and silicon nitride. In some implementations, the conductive layers include metals, such as tungsten, the first dielectric layers include silicon oxide, and the second dielectric layers include silicon nitride. For example, first material layers 302 of stack structure 201 can include tungsten in core array region 101 and conductive portion 105 of contact region 103 and silicon nitride in dielectric portion 107 of contact region 103. The second material layers 304 of stack structure 201 can include silicon oxide across core array region 101 and contact region 103.

As shown in FIGS. 2 and 3, the heights of stack structure 201 (e.g., the conductive stack structure and the dielectric stack structure) are uniform in core array region 101 and in contact region 103, according to some implementations. Different from some 3D memory devices that include one or more staircase structures in a staircase region (corresponding to contact region 103 for contact/fan-out), which has uniform heights of the stack structure in the staircase region, 3D memory device 100 can eliminate the staircase structures while still achieving the contact/fan-out function using contact structures 106.

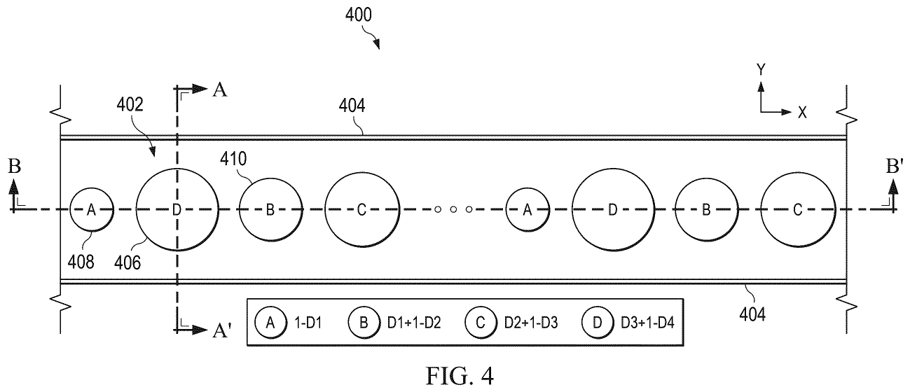

FIG. 4 illustrates a plain view of an example contact region in an example block 400 of an example 3D memory device, according to some aspects of the present disclosure. In some cases, the example contact region, the example block 400, and/or the example 3D memory device can be structurally and/or functionally similar to the contact region 103, the block 102, and/or the 3D memory device 100, respectively. As depicted, the block 400 includes a row of contact structures 402 and parallel slit structures 404. In some cases, the parallel slit structures 404 can be structurally and/or functionally similar to the parallel slit structures 108. In some cases, the block 400 includes a single finger.

The contact structures 402 are positioned along the x-direction in the block 400. In some examples, the contact structures 402 are grouped into contact structure groups based on depths of the contact structures along the z-direction perpendicular to the x-direction, each contact structure group including one or more respective contact structures. For example, as shown in FIG. 4, the contact structures are divided into four contact structure groups-contact structure groups A, B, C, and D.

In some cases, the depth of a contract structure is determined by a depth, along the z-direction, of a conductive layer coupled to (e.g., electrically connected to) the contact structure. More specifically, the example 3D memory device can include a stack of conductive layers (e.g., the first material layers 302) and isolating layers (e.g., the second material layers 304) alternating with each other along the z-direction, such as the stack structure 201. Each contact structure can extend through at least a part of the stack of conductive layers and isolating layers and is coupled to a respective conductive layer. In some cases, a conductive layer's depth is equal to or positively related to the sequence of the conductive layer in the stack of the example 3D memory device along the z-direction. So, for example, the topmost conductive layer along the z-direction can have a depth of one, while the 100^{th} conductive layer counted from the top along the z-direction can have a depth of 100. In some implementations, the depth of a contract structure is equal to or positively related to the depth of a conductive layer coupled to the contact structure. So, for example, if the depth of a conductive layer coupled to the contact structure is 100, the depth of the contract structure can be 100.

In some implementations, the depths of the contact structures in a contact structure group can be continuous. For example and as depicted in FIG. 4, the depths of the contact structures in the contact structure group A range from 1 to D₁, the depths of the contact structures in the contact structure group B range from D₁+1 to D₂, the depths of the contact structures in the contact structure group C range from D₂+1 to D₃, and the depths of the contact structures in the contact structure group D range from D₃+1 to D₄, where D₄>D₃>D₂>D₁. Accordingly, the conductive layers coupled to by the contact structures of a contact structure group can be all on the same side along the z-direction compared to the conductive layers coupled to by the contact structures of another contact structure group. So, for example, the conductive layers of the contact structure group A (ranging from 1 to D₁) are on the same side (e.g., above) along the z-direction compared to the conductive layers of the contact structure group B (range from D₁+1 to D₂). Similarly, the conductive layers of the contact structure group C (ranging from D₂+1 to D₃) are also on the same side (e.g., below) along the z-direction compared to the conductive layers of the contact structure group B (range from D₁+1 to D₂)

In some cases, the contact structures can be divided equally among the contact structure groups, so each contact structure group has about the same quantity of contact structures. In other cases, the quantities of contact structures can be different among the contact structure groups. For example, assuming that the contact structures are divided equally among the contact structure groups A, B, C, and D, then D2=2 χ D₁, D3=3×D₁, and D4=4×D₁.

In some examples, along the x-direction, between two adjacent contact structures of a first contact structure group, a contact structure of a second contact structure group different from the first contact structure group is positioned. In other words, in some examples, two contact structures of the same contact structure group are not adjacent to each other. For example, as shown in FIG. 4, the contact structures of contact structure groups A, D, B, and C alternate along the x-direction in this sequence. So, for example, the contact structure 406 of contact structure group D is next to the contact structure 408 of contact structure group A and the contact structure 410 of contact structure group B, and the contact structure 406 of contact structure group D is not next to any other contact structure of the contact structure group D.

In some cases, a depth of a contact structure group can be defined to represent the depths of the contact structures in the contact structure group. For example, the depth of the contact structure group can be the depth of the contact structure having the smallest depth among the contact structures in the contact structure group, the depth of the contact structure having the greatest depth among the contact structures in the contact structure group, or an average depth of the contact structures in the contact structure group. In some examples, the contact structures can be positioned along the x-direction in a pattern where depths of the contact structure groups alternate. For example, as shown in FIG. 4, the depths of the contact structure groups A, B, C, and D are from the smallest to the greatest. Assume that the contact structure groups A and B are shallow contact structure groups and that the contact structure groups A and B are deep contact structure groups. The contact structures are positioned along the x-direction in the sequence of contact structure groups A, D, B, and C. That is, the depths of these contact structure groups alternate between shallow and deep contact structure groups.

Stated differently, assume that a contact structure of a first contact structure group is adjacent to (i) a contact structure of a second contact structure group and (ii) a contact structure of a third contact structure group along the x-direction. In some cases, both (i) the conductive layers coupled to the contact structures of the second contact structure group and (ii) the conductive layers coupled to the contact structures of the third contact structure group are on the same side compared to the conductive layers coupled to the contact structures of the first contact structure group. For example, as shown in FIG. 4, a contact structure of the contact structure group D is adjacent to a contact structure of the contact structure group A and a contact structure of the contact structure group B along the x-direction. The conductive layers coupled to the contact structures of the contact structure group A (i.e., 1 to D₁) and the conductive layers coupled to the contact structures of the contact structure group B (i.e., D₁+1 to D₂) are on the same side (i.e., above) compared to the conductive layers coupled to the contact structures of the contact structure group D (i.e., D₃+1 to D₄).

In some cases, a deeper contact structure's fabrication process is more complicated than that of a shallower contact structure. By positioning the contact structures along the x-direction in a pattern where depths of the contact structure groups alternate, two deeper contact structures can be separated by positioning a shallower contact structure in between. Therefore, the distance between the two deeper contact structures is increased. This can improve the process window of the deeper contact structures, and reduce the difficulty of the fabrication process of the deeper contact structures. Moreover, because the two adjacent contact structures are in different contact structure groups having different depths, the two conductive layers coupled to by the two adjacent contact structures can have a large distance along the z-direction. This can enhance the structural stability of the 3D memory device. In some cases, if the two conductive layers coupled to by the two adjacent contact structures are close to each other along the z-direction, dummy channel structure(s) can be added between the two adjacent contact structures to increase the distance between the two adjacent contact structures.

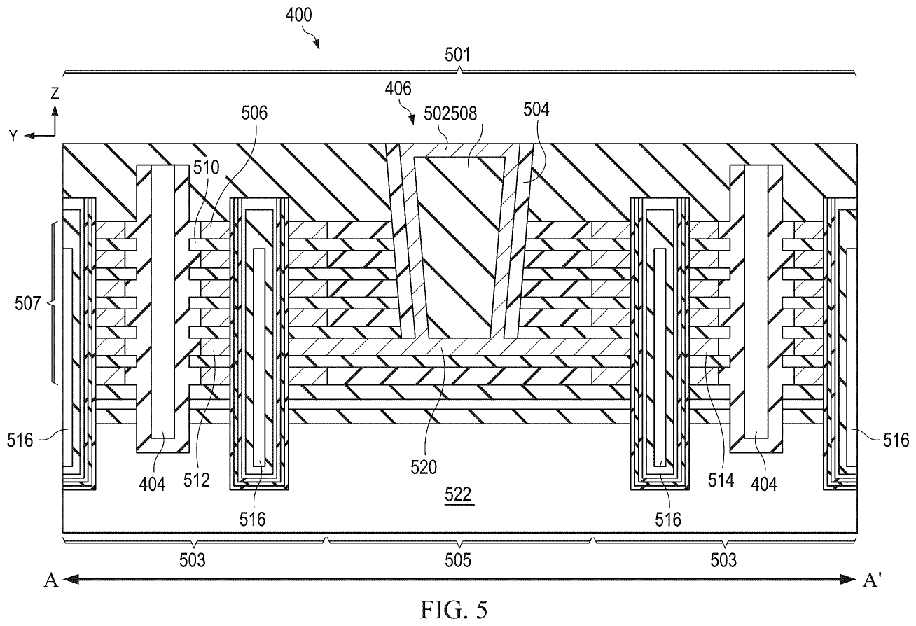

FIG. 5 depicts a cross-sectional view of the block 400 along cut line AA′ shown in FIG. 4, according to some aspects of the present disclosure. As shown, the block 400 includes dummy channel structures 516 (e.g., the dummy channel structures 112) in conductive portions 503 (e.g., the conductive portions 105) of contact region 501 (e.g., the contact region 103). Each dummy channel structure 516 can extend vertically through interleaved conductive layers 506 (e.g., the first material layers 302) and first dielectric layers 510 (e.g., the second material layers 304) of the stack structure 507 (e.g., the stack structure 201) into substrate 522 (e.g., the substrate 203). As noted in FIG. 4, the block 400 can include slit structures 404. Each slit structure 404 can extend vertically through interleaved conductive layers 506 and first dielectric layers 510 of the stack structure 507 into substrate 522 as well.

In some implementations, contact structure 406 includes a vertical contact 502, a contact spacer 504 circumscribing vertical contact 502, and an interconnect line 520 below and in contact with vertical contact 502. Vertical contact 502 and interconnect line 520 can include conductive materials including, but not limited to, W, Co, Cu, Al, TiN, polysilicon, doped silicon, silicides, or any combination thereof. Contact spacer 504 can include dielectric materials including, but not limited to, silicon oxide, silicon nitride, silicon oxynitride, or any combination thereof. In some implementations, vertical contact 502 and interconnect line 520 include TiN/W, and contact spacer 504 includes silicon oxide.

In some implementations as shown in FIG. 5, contact structure 406 includes a filler 508 circumscribed by vertical contact 502. In some cases, the contact opening may not be fully filled with contact spacer 504 and vertical contact 502, and the remaining space of the contact opening may be filled with dielectric materials, including, but not limited to, silicon oxide, silicon nitride, silicon oxynitride, or any combination thereof, as filler 508.

In some cases, as shown in FIG. 5, the block 400 includes two word lines 512 and 514. On the y-direction, the word line 512 is positioned on a side of the block 400 adjacent to a slit structure 404, while the other word line 514 is positioned on the other side of the block 400 adjacent to another slit structure 404. As depicted, the contact structure 406 is coupled to both word lines 512 and 514 via the interconnect line 520.

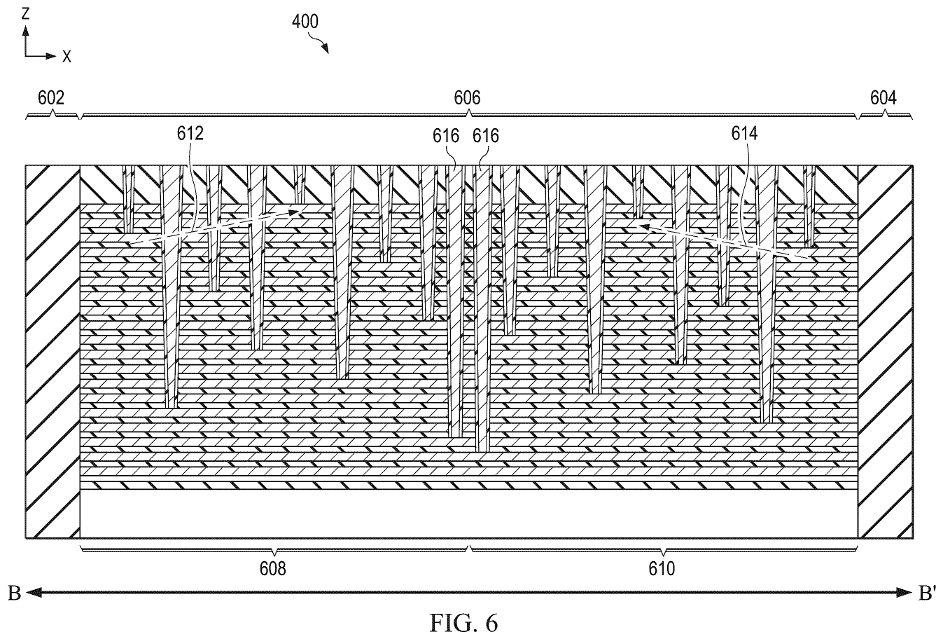

FIG. 6 depicts an example cross-sectional view of the block 400 along cut line BB′ shown in FIG. 4, according to some aspects of the present disclosure. As shown, the block 400 includes contact region 606 (e.g., the contact region 103) and core array regions 602 and 604 (e.g., the core array region 101). The contact region 606 can include two halves along the x-direction: the left half 608 and the right half 610, each half including a plurality of contact structures.

In some examples, contact structures of a contact structure group are positioned in a pattern that the contact structures having odd depths (e.g., 1, 3, 5, and so on) are positioned on one half of the block 400 along the x-direction, whereas the contact structures having even depths (e.g., 2, 4, 6, and so on) are positioned on the other half of the block 400 along the x-direction. For example, for contact structure group A, the contact structures having the depths of 1, 3, 5, . . . . D₁ can be positioned on the left half 608, assuming that D₁ is an odd number, and the contact structures having the depths of 2, 4, 6, . . . . D₁−1 can be positioned on the right half 610 along the x-direction. The grouping of even-depth contact structures on one side and the grouping of odd-depth contact structures on the other side can more efficiently and effectively detect BVC leakages.

In some cases, contact structures of a contact structure group are positioned in a pattern that the deep contact structures are positioned on two sides of the block 400 along the x-direction, whereas the shallow contact structures are positioned at the center of the block 400 along the x-direction. So, taking contact structure group A for example, assume that the contact structures having odd depths are on the left half 608, the contact structures from left to right along the x-direction can have the depths of D₁, D₁−2, D₁−4, . . . , 1, assuming that D₁ is an odd number. The contact structure having the depth of 1 is at the middle of the contact region 606. Similarly, assume that the contact structures having even depths are on the right half 610, the contact structures from right to left along the x-direction can have the depths of D₁−1, D₁−3, D₁−5, . . . , 2, assuming that D₁ is an odd number. The contact structure having the depth of 2 is at the middle of the contact region 606. The arrows 612 and 614 illustrate such depth trends on the left half 608 and the right half 610, respectively. By positioning the deep contact structures on two sides of the block 400 and placing the shallow contact structures at the center of the block 400, a process window of the contact structures can be increased.

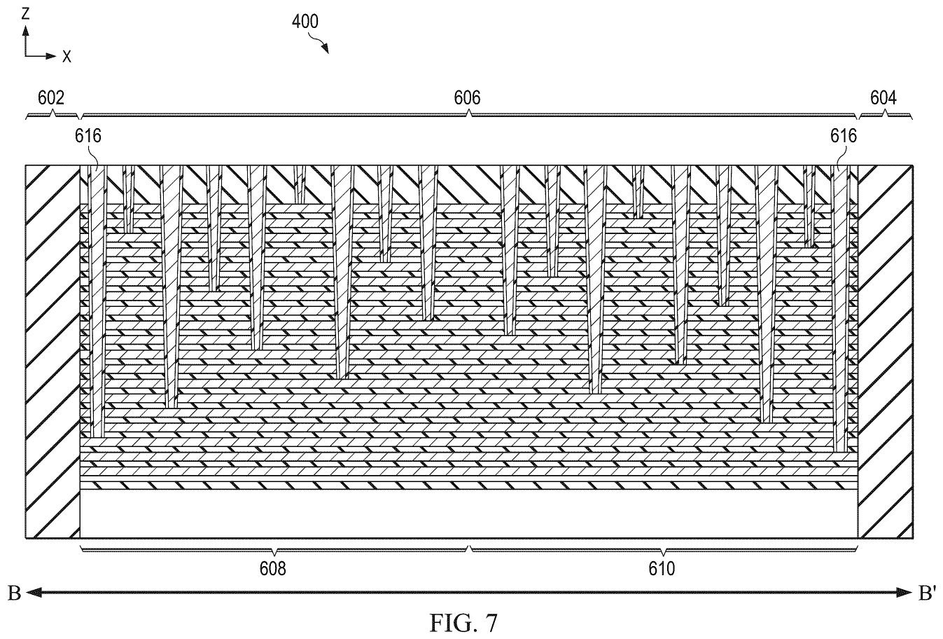

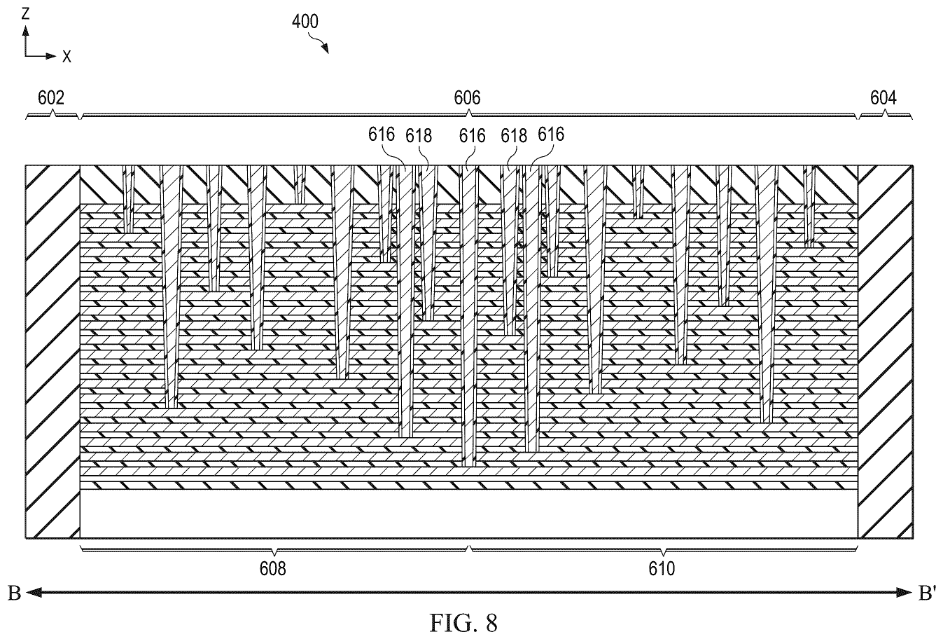

In some examples, two contact structures 616 corresponding to the BSGs are positioned at the center of the contact region 606, as depicted in FIG. 6. Positioning the contact structures corresponding to the BSGs at the center of a contact region can enhance the BSG word line driver control. Although not shown in FIG. 6, it is understood that the contact structures corresponding to BSGs can be positioned in other locations different from the center of a contact region. FIGS. 7-8 show two other example implementations of positioning the contact structures corresponding to BSGs.

FIG. 7 depicts another example cross-sectional view of the block 400 along cut line BB′ shown in FIG. 4, according to some aspects of the present disclosure. Compared to FIG. 6, the difference in FIG. 7 is that the contact structures 616 corresponding to the BSGs are positioned at two ends of the contact region 606 along the x-direction. The contact structures 616 can be adjacent to the core array regions 602 and 604, respectively.

FIG. 8 depicts yet another example cross-sectional view of the block 400 along cut line BB′ shown in FIG. 4, according to some aspects of the present disclosure. Compared to FIG. 6, the difference in FIG. 7 is that the contact structures 616 corresponding to the BSGs are interleaved with other contact structures not corresponding to the BSGs, such as the contact structures 618. In other words, there can be other contact structure(s) not corresponding to the BSGs positioned in between two adjacent contact structures 616 corresponding to the BSGs.

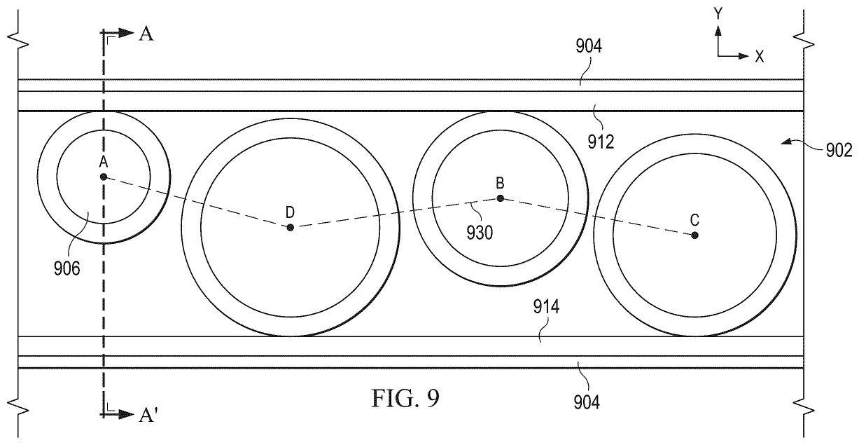

FIG. 9 illustrates a plain view of an example contact region in an example block 900 of an example 3D memory device, according to some aspects of the present disclosure. In some cases, the example contact region, the example block 900, and/or the example 3D memory device can be structurally and/or functionally similar to the contact region 103, the block 102, and/or the 3D memory device 100, respectively. As depicted, the block 900 includes a row of contact structures 902 and parallel slit structures 904. In some cases, the parallel slit structures 904 can be structurally and/or functionally similar to the parallel slit structures 108. In some cases, the block 900 includes a single finger.

The contact structures 902 are positioned along the x-direction in the block 900. Similar to FIG. 4, the contact structures 902 are grouped into contact structure groups A, B, C, and D based on depths of the contact structures along the z-direction. As depicted, the x-direction and the y-direction form a x-y plane. A projection of each of the contact structures 902 on the x-y plane is a circle-like shape, and includes a respective center point. Each center point has a respective height along the y-direction, for example, as compared to the lower slit structure 904. As depicted in FIG. 9, in some cases, the contact structures 902 are positioned along the x-direction in a wave-like pattern where heights of center points of the contact structures 902 alternate. For example, the four contact structures 902 depicted in FIG. 9 show alternating heights of center points (i.e., relatively high center point, relatively low center point, relatively high center point, and relatively low center point), as illustrated by the line 930.

By positioning the contact structures 902 in this wave-like pattern, the contact structures 902 can be closely positioned by reducing the distances between adjacent contact structures 902. This can reduce the overall length of the contact region along the x-direction and thus increase the space for the core array regions. The increased space for the core array regions can in turn increase the space for channel structures, and thus increase the memory density.

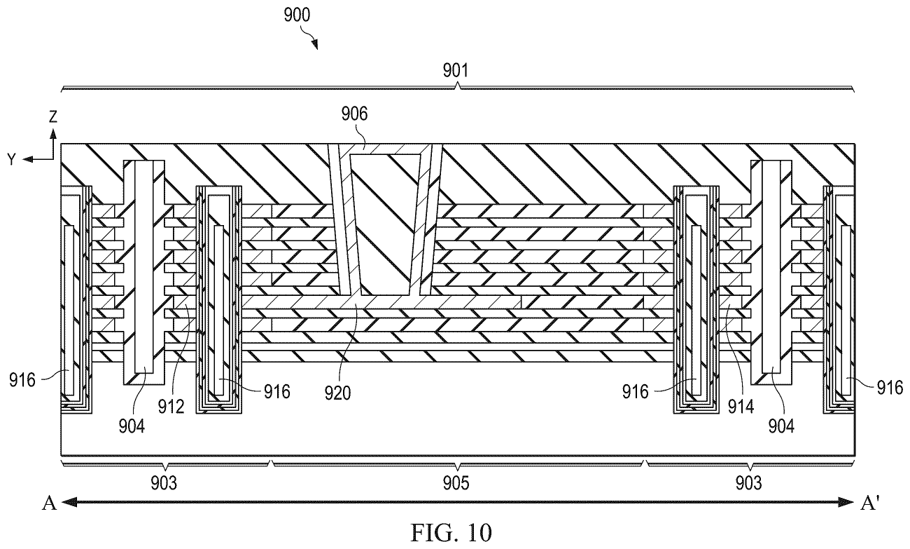

FIG. 10 depicts a cross-sectional view of the block 900 along cut line AA′ shown in FIG. 9, according to some aspects of the present disclosure. As shown, the block 900 includes dummy channel structures 916 (e.g., the dummy channel structures 112) in conductive portions 903 (e.g., the conductive portions 105) of contact region 901 (e.g., the contact region 103). Each dummy channel structure 916 can extend vertically through the stack structure (e.g., the stack structure 201) into a substrate (e.g., the substrate 203). As noted in FIG. 9, the block 900 can include slit structures 904. Each slit structure 904 can extend vertically through the stack structure into the substrate as well.

In some cases, as shown in FIG. 10, the block 900 includes two word lines 912 and 914. On the y-direction, the word line 912 is positioned on a side of the block 900 adjacent to a slit structure 904, while the other word line 914 is positioned on the other side of the block 900 adjacent to another slit structure 904. As the contact structure 906 is closer to the left slit structure 904 than the right slit structure 904, the contact structure 906 is coupled to the word line 912 via the interconnect line 920 but is not coupled to the word line 914.

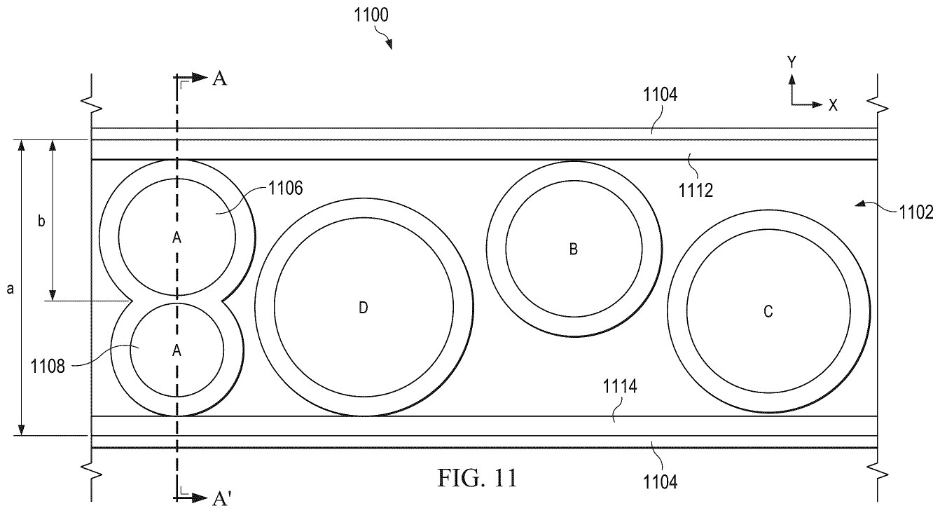

FIG. 11 illustrates a plain view of an example contact region in an example block 1100 of an example 3D memory device, according to some aspects of the present disclosure. In some cases, the example contact region, the example block 1100, and/or the example 3D memory device can be structurally and/or functionally similar to the contact region 103, the block 102, and/or the 3D memory device 100, respectively. As depicted, the block 1100 includes contact structures 1102 and parallel slit structures 1104. In some cases, the parallel slit structures 1104 can be structurally and/or functionally similar to the parallel slit structures 108. In some cases, the block 1100 includes a single finger.

The contact structures 1102 are positioned along the x-direction in the block 1100. Similar to FIG. 4, the contact structures 1102 are grouped into contact structure groups A, B, C, and D based on depths of the contact structures 1102 along the z-direction. Moreover, the contact structures 1102 are positioned in a wave-like pattern as discussed in FIG. 9, except that two rows of contact structures of the contact structure group A, including contact structures 1106 and 1108, are positioned parallelly along the x-direction.

As discussed in FIG. 4, the depth of the contact structure group A (ranging from 1 to D₁) is the smallest among all contact structure groups. Therefore, there can be enough space along the y-direction of a block to position two rows of the contact structures of the contact structure group A. Assume that the height of the block 1100 is a, measured as the distance along the y-direction between the parallel slit structures 1104. Also assume that a length of a projection of the contact structure 1106 is b, measured as, for example, the diameter of the projection of the contact structure on the x-y plane. In some cases, the length b needs to be smaller than or equal to one half of the height a of the block 1100 to be able to position two rows of contact structures.

By positioning the contact structures in two rows, the density of the contact structures in the contact region can be further increased, as compared to, for example, that of the contact region depicted in FIG. 9. This can reduce the overall length of the contact region along the x-direction and thus increase the space for the core array regions. The increased space for the core array regions can in turn increase the space for channel structures, and thus increase the memory density.

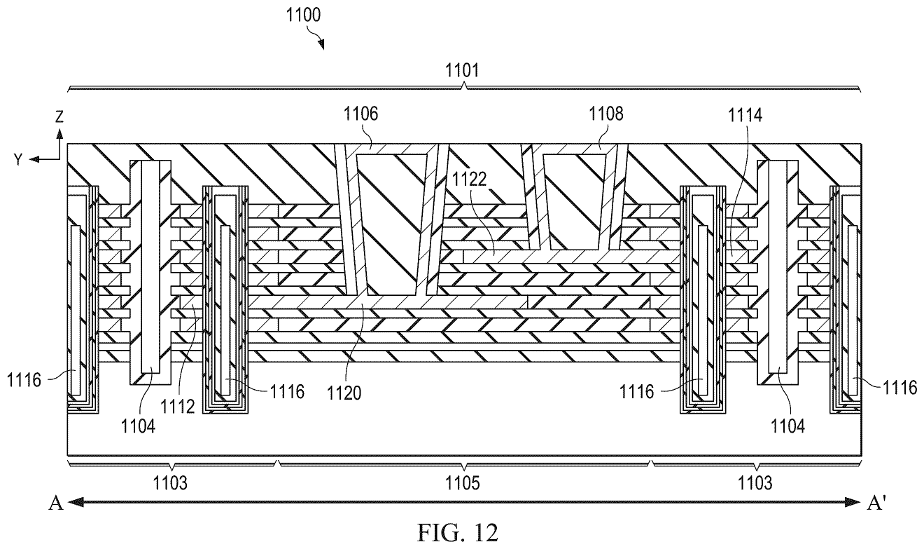

FIG. 12 depicts a cross-sectional view of the block 1100 along cut line AA′ shown in FIG. 11, according to some aspects of the present disclosure. As shown, the block 1100 includes dummy channel structures 1116 (e.g., the dummy channel structures 112) in conductive portions 1103 (e.g., the conductive portions 105) of contact region 1101 (e.g., the contact region 103). Each dummy channel structure 1116 can extend vertically through the stack structure (e.g., the stack structure 201) into a substrate (e.g., the substrate 203). As noted in FIG. 11, the block 1100 can include slit structures 1104. Each slit structure 1104 can extend vertically through the stack structure into the substrate as well.

In some cases, as shown in FIG. 12, the block 1100 includes two word lines 1112 and 1114. On the y-direction, the word line 1112 is positioned on a side of the block 1100 adjacent to a slit structure 1104, while the other word line 1114 is positioned on the other side of the block 1100 adjacent to another slit structure 1104. As depicted, the contact structure 1106 is coupled to the word line 1112 via the interconnect line 1120, and the contact structure 1108 is coupled to the word line 1114 via the interconnect line 1122. As the contact structure 1106 and the contact structure 1108 have different depths, their interconnect lines are not at the same layer. This enables a part of the interconnect line 1120 and a part of the interconnect line 1122 to overlap on the y-direction.

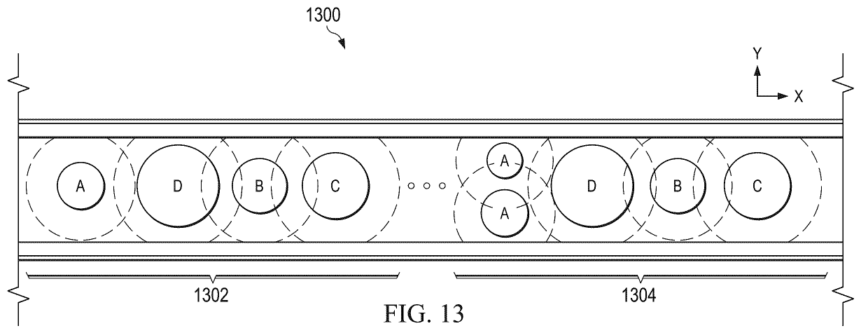

Any combination of the contact structure positionings described with respect to FIGS. 4-12 can be implemented in one block. FIG. 13 depicts an example of a block 1300 that employs two different types of contact structure positionings in different regions of the block 1300, according to some aspects of the present disclosure. Particularly, the region 1302 employs a contact structure positioning similar to that described with respect to FIG. 4. Different from the region 1302, the region 1304 employs a contact structure positioning similar to that described with respect to FIG. 11, where two rows of contact structures of the contact structure group A are positioned parallelly along the x-direction.

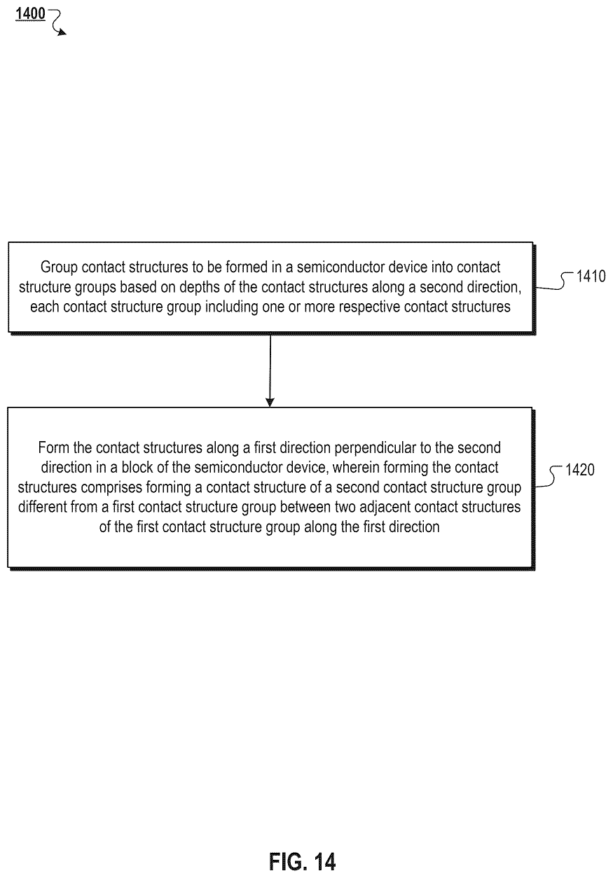

FIG. 14 is a flow chart of an example process 1400 of forming contact structures in a semiconductor device, according to some aspects of the present disclosure. The semiconductor device can be similar to, or same as, the 3D memory device 100 of FIGS. 1-3, or a part of the 3D memory device 100. The process 1400 can be described in view of FIGS. 1-3. The process 1400 can include the fabrication process of forming the contact structures in FIGS. 4-13. The process 1400 includes steps that can be performed with any suitable order and/or any combination.

At step 1410, contact structures to be formed (e.g., the contact structures 106 of FIGS. 1-3, the contact structures 402 of FIG. 4, the contact structures 902 of FIG. 9, or the contact structures 1102 of FIG. 11) in a semiconductor device (e.g., the 3D memory device 100 of FIGS. 1-3) are grouped into contact structure groups (e.g., the contact structure groups A, B, C, and D described with respect to FIGS. 4-13) based on depths of the contact structures along a second direction (e.g., the z-direction). Each contact structure group includes one or more respective contact structures.

At step 1420, the contact structures are formed along a first direction (e.g., the x-direction) perpendicular to the second direction in a block (e.g., the block 102 of FIG. 1, the block 400 of FIGS. 4-8, the block 900 of FIGS. 9-10, the block 1100 of FIGS. 11-12, or the block 1300 of FIG. 13) of the semiconductor device. Forming the contact structures can include forming a contact structure of a second contact structure group different from a first contact structure group between two adjacent contact structures of the first contact structure group along the first direction.

In some cases, a stack (e.g., the stack structure 201 of FIGS. 2-3, the stack structure 507 of FIG. 5 or the stack structure 507 of FIG. 5) of conductive layers (e.g., the first material layers 302 of FIG. 3 or the conductive layers 506 of FIG. 5) and isolating layers (e.g., the second material layers 304 of FIG. 3 or the first dielectric layers 510 of FIG. 5) alternating with each other along the second direction is formed. Each contact structure extends through at least a part of the stack of conductive layers and isolating layers. Each contact structure is coupled to a respective conductive layer. A depth of a contact structure along the second direction is determined by a depth, along the second direction, of a conductive layer coupled to the contact structure.

In some examples, all contact structures of the first contact structure group are coupled to first conductive layers. All contact structures of the second contact structure group are coupled to second conductive layers. The first conductive layers are on a first side of the second conductive layers along the second direction, for example, as illustrated in FIG. 4.

In some cases, the contact structure groups include a third contact structure group. Forming the contact structures can include forming a contact structure of the third contact structure group between a contact structure of the first contact structure group and a contact structure of the second contact structure group, and coupling all contact structures of the third contact structure group to third conductive layers. The third conductive layers are on a second side of the second conductive layers along the second direction, and the second side is opposite to the first side, for example, as illustrated in FIGS. 4-8.

In some implementations, the block includes one finger. In some cases, the first direction and a third direction (e.g., the y-direction) perpendicular to the first direction form a first plane (e.g., the x-y plane). The second direction is perpendicular to the first plane. A projection of each of the contact structures on the first plane includes a respective center point. Each center point has a respective height along the third direction. Forming the contact structures can include forming the contact structures along the first direction in a pattern where heights of center points of the contact structures alternate, for example, as illustrated in FIGS. 9-10.

In some cases, forming the contact structures can include forming two rows of contact structures of the first contact structure group parallelly along the first direction, and forming one row of contact structures of the second contact structure group along the first direction, where a depth associated with the first contact structure group is smaller than a depth associated with the second contact structure group, for example, as illustrated in FIGS. 11-12.

In some examples, the first direction and a third direction perpendicular to the first direction form a first plane. The second direction is perpendicular to the first plane. A projection of a contact structure of the first contact structure group on the first plane has a length along the third direction. The length is smaller than one half of a height of the block along the third direction, for example, as illustrated in FIGS. 9-10.

In some cases, two word lines are formed in the block, where each word line is formed on a side of the block. A contact structure of the contact structures is coupled to at least one of the two word lines, for example, as illustrated in FIGS. 5, 10, and 12.

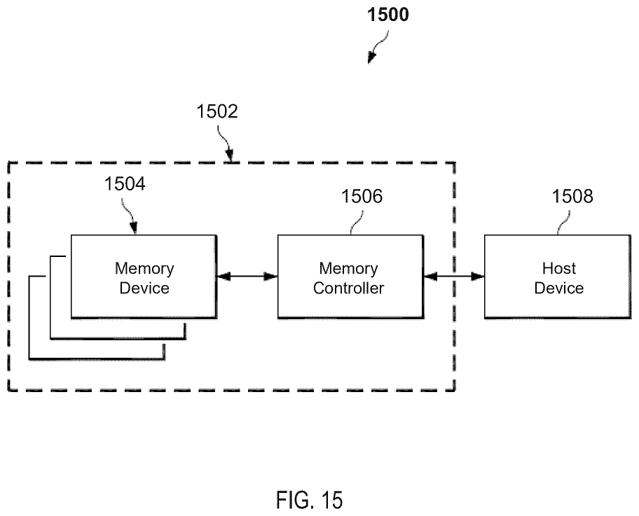

FIG. 15 illustrates a block diagram of a system 1500 having one or more semiconductor devices (e.g., memory devices), according to some aspects of the present disclosure. The system 1500 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 15, the system 1500 can include a host device 1508 and a memory system 1502 having one or more 3D memory devices 1504 and a memory controller 1506. Host device 1508 can include a processor of an electronic device, such as a central processing unit (CPU), or a system-on-chip (SoC), such as an application processor (AP). Host device 1508 can be configured to send or receive data to or from the one or more 3D memory devices 1504.

A 3D memory device 1504 can be any 3D memory device disclosed herein, such as 3D memory device depicted in FIGS. 1A-1B. In some implementations, a 3D memory device 1504 includes a NAND Flash memory. Memory controller 1506 (a.k.a., a controller circuit) is coupled to 3D memory device 1504 and host device 1508. Consistent with implementations of the present disclosure, 3D memory device 1504 can include a plurality of conductive interconnections through a cover layer that are in contact with conductive pads in a conductive pad layer, and memory controller 1506 can be coupled to 3D memory device 1504 through at least one of the plurality of conductive interconnections. Memory controller 1506 is configured to control 3D memory device 1504. For example, memory controller 1506 may be configured to operate a plurality of channel structures via word lines. Memory controller 1506 can manage data stored in 3D memory device 1504 and communicate with host device 1508.

In some implementations, memory controller 1506 is designed/configured for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 1506 is designed/configured for operating in a high duty cycle environment SSDs or embedded multi-media-cards (eMMCs) used as data storage for mobile devices, such as smartphones, tablets, laptop computers, etc., and enterprise storage arrays. Memory controller 1506 can be configured to control operations of 3D memory device 1504, such as read, erase, and program (or write) operations. Memory controller 1506 can also be configured to manage various functions with respect to the data stored or to be stored in 3D memory device 1504 including, but not limited to bad-block management, garbage collection, logical-to-physical address conversion, wear leveling, etc. In some implementations, memory controller 1506 is further configured to process error correction codes (ECCs) with respect to the data read from or written to 3D memory device 1504. Any other suitable functions may be performed by memory controller 1506 as well, for example, formatting 3D memory device 1504.

Memory controller 1506 can communicate with an external device (e.g., host device 1508) according to a particular communication protocol. For example, memory controller 1506 may communicate with the external device through at least one of various interface protocols, such as a USB protocol, an MMC protocol, a peripheral component interconnection (PCI) protocol, a PCIexpress (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

Memory controller 1506 and one or more 3D memory devices 1504 can be integrated into various types of storage devices, for example, be included in the same package, such as a universal Flash storage (UFS) package or an eMMC package. That is, memory system 1502 can be implemented and packaged into different types of end electronic products. In one example as shown in FIG. 15, memory controller 1506 and a single 3D memory device 1504 may be integrated into a memory system 1502. Memory system 1502 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc.

Implementations of the subject matter and the actions and operations described in this present disclosure can be implemented in digital electronic circuitry, in tangibly-embodied computer software or firmware, in computer hardware, including the structures disclosed in this present disclosure and their structural equivalents, or in combinations of one or more of them. Implementations of the subject matter described in this present disclosure can be implemented as one or more computer programs, e.g., one or more modules of computer program instructions, encoded on a computer program carrier, for execution by, or to control the operation of, data processing apparatus. The carrier may be a tangible non-transitory computer storage medium. Alternatively, or in addition, the carrier may be an artificially-generated propagated signal, e.g., a machine-generated electrical, optical, or electromagnetic signal, that is generated to encode information for transmission to suitable receiver apparatus for execution by a data processing apparatus. The computer storage medium can be or be part of a machine-readable storage device, a machine-readable storage substrate, a random or serial access memory device, or a combination of one or more of them. A computer storage medium is not a propagated signal.

It is noted that references in the present disclosure to “one embodiment,” “an embodiment,” “an example embodiment,” “some implementations,” “some implementations,” etc., indicate that the embodiment described can include a particular feature, structure, or characteristic, but every embodiment can not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to affect such feature, structure or characteristic in connection with other implementations whether or not explicitly described.

In general, terminology can be understood at least in part from usage in context. For example, the term “one or more” as used herein, depending at least in part upon context, can be used to describe any feature, structure, or characteristic in a singular sense or can be used to describe combinations of features, structures or characteristics in a plural sense. Similarly, terms, such as “a,” “an,” or “the,” again, can be understood to convey a singular usage or to convey a plural usage, depending at least in part upon context. In addition, the term “based on” can be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner, such that “on” not only means “directly on” something, but also includes the meaning of “on” something with an intermediate feature or a layer therebetween. Moreover, “above” or “over” not only means “above” or “over” something, but can also include the meaning it is “above” or “over” something with no intermediate feature or layer therebetween (i.e., directly on something).

Further, spatially relative terms, such as “beneath,” “below,” “lower,” “above,” “upper,” and the like, can be used herein for ease of description to describe one element or feature's relationship to another element(s) or feature(s) as illustrated in the figures. The spatially relative terms are intended to encompass different orientations of the device in use or process step in addition to the orientation depicted in the figures. The apparatus can be otherwise oriented (rotated 90 degrees or at other orientations) and the spatially relative descriptors used herein can likewise be interpreted accordingly.

As used herein, the term “substrate” refers to a material onto which subsequent material layers are added. The substrate includes a “top” surface and a “bottom” surface. The top surface of the substrate is typically where a semiconductor device is formed, and therefore the semiconductor device is formed at a top side of the substrate unless stated otherwise. The bottom surface is opposite to the top surface and therefore a bottom side of the substrate is opposite to the top side of the substrate. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically noN+ conductive material, such as a glass, a plastic, or a sapphire wafer.

As used herein, the term “layer” refers to a material portion including a region with a thickness. A layer has a top side and a bottom side where the bottom side of the layer is relatively close to the substrate and the top side is relatively away from the substrate. A layer can extend over the entirety of an underlying or overlying structure, or can have an extent less than the extent of an underlying or overlying structure. Further, a layer can be a region of a homogeneous or inhomogeneous continuous structure that has a thickness less than the thickness of the continuous structure. For example, a layer can be located between any set of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductive and contact layers (in which contacts, interconnect lines, and/or vertical interconnect accesses (VIAs) are formed) and one or more dielectric layers.

As used herein, the term “nominal/nominally” refers to a desired, or target, value of a characteristic or parameter for a component or a process step, set during the design phase of a product or a process, together with a range of values above and/or below the desired value. As used herein, the range of values can be due to slight variations in manufacturing processes or tolerances. As used herein, the term “about” indicates the value of a given quantity that can vary based on a particular technology node associated with the subject semiconductor device. Based on the particular technology node, the term “about” can indicate a value of a given quantity that varies within, for example, 10-30% of the value (e.g., .+−.10%, .+−.20%, or .+−.30% of the value).

In the present disclosure, the term “horizontal/horizontally/lateral/laterally” means nominally parallel to a lateral surface of a substrate, and the term “vertical” or “vertically” means nominally perpendicular to the lateral surface of a substrate.

As used herein, the term “3D memory” refers to a three-dimensional (3D) semiconductor device with vertically oriented strings of memory cell transistors (referred to herein as “memory strings,” such as NAND strings) on a laterally-oriented substrate so that the memory strings extend in the vertical direction with respect to the substrate.

The present disclosure provides many different implementations, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include implementations in which the first and second features may be in direct contact, and may also include implementations in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various implementations and/or configurations discussed.

The foregoing description of the specific implementations can be readily modified and/or adapted for various applications. Therefore, such adaptations and modifications are intended to be within the meaning and range of equivalents of the disclosed implementations, based on the teaching and guidance presented herein.

While the present disclosure contains many specific implementation details, these should not be construed as limitations on the scope of what is being claimed, which is defined by the claims themselves, but rather as descriptions of features that may be specific to particular implementations of particular inventions. Certain features that are described in this present disclosure in the context of separate implementations can also be implemented in combination in a single embodiment. Conversely, various features that are described in the context of a single embodiment can also be implemented in multiple implementations separately or in any suitable sub-combination. Moreover, although features may be described above as acting in certain combinations and even initially be claimed as such, one or more features from a claimed combination can in some cases be excised from the combination, and the claim may be directed to a sub-combination or variation of a sub-combination.

Similarly, while operations are depicted in the drawings and recited in the claims in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the implementations described above should not be understood as requiring such separation in all implementations, and it should be understood that the described program components and systems can generally be integrated together in a single software product or packaged into multiple software products.

Particular implementations of the subject matter have been described. Other implementations also are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing may be advantageous.

The breadth and scope of the present disclosure should not be limited by any of the above-described exemplary implementations, but should be defined only in accordance with the following claims and their equivalents.

What is claimed is:

1. A semiconductor device comprising contact structures, wherein:
the contact structures are positioned along a first direction in a block of the semiconductor device;
the contact structures are grouped into contact structure groups based on depths of the contact structures along a second direction perpendicular to the first direction, each contact structure group comprising one or more respective contact structures; and
between two adjacent contact structures of a first contact structure group along the first direction, a contact structure of a second contact structure group different from the first contact structure group is positioned.

2. The semiconductor device of claim 1, comprising a stack of conductive layers and isolating layers alternating with each other along the second direction, wherein each contact structure extends through at least a part of the stack of conductive layers and isolating layers, each contact structure is coupled to a respective conductive layer, and a depth of a contact structure along the second direction is determined by a depth, along the second direction, of a conductive layer coupled to the contact structure.

3. The semiconductor device of claim 2, wherein all contact structures of the first contact structure group are coupled to first conductive layers, all contact structures of the second contact structure group are coupled to second conductive layers, and the first conductive layers are on a first side of the second conductive layers along the second direction.

4. The semiconductor device of claim 3, wherein the contact structure groups comprise a third contact structure group, all contact structures of the third contact structure group are coupled to third conductive layers, the third conductive layers are on a second side of the second conductive layers along the second direction, the second side is opposite to the first side, and a contact structure of the third contact structure group is positioned between a contact structure of the first contact structure group and a contact structure of the second contact structure group.

5. The semiconductor device of claim 1, wherein the block comprises one finger.

6. The semiconductor device of claim 1, wherein the first direction and a third direction perpendicular to the first direction form a first plane, the second direction is perpendicular to the first plane, a projection of each of the contact structures on the first plane comprises a respective center point, each center point has a respective height along the third direction, and the contact structures are positioned along the first direction in a pattern where heights of center points of the contact structures alternate.

7. The semiconductor device of claim 1, wherein two rows of contact structures of the first contact structure group are positioned parallelly along the first direction, one row of contact structures of the second contact structure group are positioned along the first direction, and a depth associated with the first contact structure group is smaller than a depth associated with the second contact structure group.

8. The semiconductor device of claim 7, wherein the first direction and a third direction perpendicular to the first direction form a first plane, the second direction is perpendicular to the first plane, a projection of a contact structure of the first contact structure group on the first plane has a length along the third direction, and the length is smaller than one half of a height of the block along the third direction.

9. The semiconductor device of claim 1, wherein the block comprises two word lines, each word line is positioned on a side of the block, and a contact structure of the contact structures is coupled to at least one of the two word lines.

10. The semiconductor device of claim 1, wherein a first contact structure and a second contact structure of the first contact structure group are adjacent to each other along a third direction perpendicular to the first direction, the first contact structure is coupled to a first side of the block via a first interconnect line, the second contact structure is coupled to a second side of the block via a second interconnect line, and at least a part of the first interconnect line and at least a part of the second interconnect line overlap on the third direction.

11. A method, comprising:
grouping contact structures to be formed in a semiconductor device into contact structure groups based on depths of the contact structures along a second direction, each contact structure group comprising one or more respective contact structures; and
forming the contact structures along a first direction perpendicular to the second direction in a block of the semiconductor device, wherein forming the contact structures comprises forming a contact structure of a second contact structure group different from a first contact structure group between two adjacent contact structures of the first contact structure group along the first direction.

12. The method of claim 11, comprises:
forming a stack of conductive layers and isolating layers alternating with each other along the second direction, wherein each contact structure extends through at least a part of the stack of conductive layers and isolating layers, each contact structure is coupled to a respective conductive layer, and a depth of a contact structure along the second direction is determined by a depth, along the second direction, of a conductive layer coupled to the contact structure.

13. The method of claim 12, wherein forming the contact structures comprises:
coupling all contact structures of the first contact structure group to first conductive layers; and
coupling all contact structures of the second contact structure group to second conductive layers, wherein the first conductive layers are on a first side of the second conductive layers along the second direction.

14. The method of claim 13, wherein the contact structure groups comprise a third contact structure group, and wherein forming the contact structures comprises:
forming a contact structure of the third contact structure group between a contact structure of the first contact structure group and a contact structure of the second contact structure group; and
coupling all contact structures of the third contact structure group to third conductive layers, wherein the third conductive layers are on a second side of the second conductive layers along the second direction, and the second side is opposite to the first side.

15. The method of claim 11, wherein the block comprises one finger.

16. The method of claim 11, wherein the first direction and a third direction perpendicular to the first direction form a first plane, the second direction is perpendicular to the first plane, a projection of each of the contact structures on the first plane comprises a respective center point, each center point has a respective height along the third direction, and forming the contact structures comprises:
forming the contact structures along the first direction in a pattern where heights of center points of the contact structures alternate.

17. The method of claim 11, wherein forming the contact structures comprises:
forming two rows of contact structures of the first contact structure group parallelly along the first direction; and
forming one row of contact structures of the second contact structure group along the first direction, wherein a depth associated with the first contact structure group is smaller than a depth associated with the second contact structure group.

18. The method of claim 17, wherein the first direction and a third direction perpendicular to the first direction form a first plane, the second direction is perpendicular to the first plane, a projection of a contact structure of the first contact structure group on the first plane has a length along the third direction, and the length is smaller than one half of a height of the block along the third direction.

19. The method of claim 11, comprising:
forming two word lines in the block, wherein each word line is formed on a side of the block; and
coupling a contact structure of the contact structures to at least one of the two word lines.

20. A system, comprising:
a semiconductor device comprising contact structures, wherein:
the contact structures are positioned along a first direction in a block of the semiconductor device;
the contact structures are grouped into contact structure groups based on depths of the contact structures along a second direction perpendicular to the first direction, each contact structure group comprising one or more respective contact structures; and
between two adjacent contact structures of a first contact structure group along the first direction, a contact structure of a second contact structure group different from the first contact structure group is positioned; and
a memory controller electrically connected to the semiconductor device, wherein the memory controller is configured to control the semiconductor device.
